(19) United States
(12) Patent Application Publication
(10) Pub. No.: US 2001/0004314 A1
(43) Pub. Date: Jun. 21, 2001

(54) Module with thin-film circuit comprising a trimmable capacitor

(76) Inventors: Carlo Copetti, Aachen (DE); Martin Fleuster, Aachen (DE); Franciscus Sanders, Eindhoven (NL)

Correspondence Address: JACK E. HAKEN, c/o U.S. PHILIPS CORPORATION, Intellectual Property Department, 580 White Plains Road, Tarrytown, NY, 10591, US

(21) Appl. No.: 09/734,807

(22) Filed: Dec. 12, 2000

(30) Foreign Application Priority Data
Dec. 21, 1999 (DE) 19961675.2

(51) Int. Cl. H05K 1/16

(52) U.S. Cl. 361/765

(57) ABSTRACT

The invention relates to a module provided with a thin-film circuit which comprises an integrated trimmable capacitor. At least one electrically conducting layer (2, 4) of the capacitor has a structured surface with recesses. This finger-type design has the result that the actual capacitor is composed of several capacitors connected in parallel. After the total capacitance value has been determined, this total capacitance value can be fine tuned through a selective cutting-off of fingers, i.e. of capacitors, from the main surface of the electrically conducting layer (2, 4).

The invention relates to a module provided with a thin-film circuit on a substrate of an insulating material which comprises at least one passive component, as well as to a method of fine tuning the capacitance value of said passive component.

The development of numerous electronic devices is characterized by the following trends: miniaturization, higher reliability, lower or at least constant prices accompanied by an enhanced functionality. Experience has shown that the number of passive components accounts for 70% of the number of components present in practice in many consumer electronics appliances, for example in TV sets or video recorders. The stormy developments in the field of mobile telephones, the continuous miniaturization of cordless telephone appliances, and the use of higher frequencies lead to higher requirements being imposed on the individual components. The continuing miniaturization in particular has the result that fluctuations in the basic materials and in the manufacturing processes of the passive electronic components have a comparatively strong influence on the final electrical specification.

This is particularly true for the capacitance value which, in the case of a single-layer capacitor, is given by the product of the effective electrode surface area and the dielectric constant divided by the thickness of the dielectric layer.

A possibility of keeping the manufacturing cost as low as possible is offered by the manufacture of discrete passive electronic components such as capacitors, resistors, and inductors, with a wide range of specifications which can be adjusted by corrective measures afterwards (fine tuning) so as to achieve the desired final specification.

The forward march of miniaturization, however, also renders the production, handling, and mounting of discrete passive components increasingly difficult. This problem may be solved in that integrated passive components (IPCs) are used. In this technology, passive components such as, for example, resistors (R), capacitors (C), or inductors (L) are combined into integrated basic circuits and systems. In the field of thin-film technology, so-called thin-film circuits are obtained on carrier plates of an insulating material by means of masks, which circuits are the equivalents of printed circuits on a very strongly reduced scale. The manufacture of thin-film circuits is known and is achieved in general by means of various consecutive coating and structuring processes.

Vapor deposition methods and sputtering methods are used for depositing the various layers. In these methods, fluctuations in the thickness of the layers may have a major influence in combination with the small lateral dimensions of the passive components. The capacitance value of a capacitor is thus determined by the effective electrode surface area as well as by the thickness of the dielectric layer. A better process control in the manufacture of the passive electronic components leads to a higher process cost.

The invention has for its object to provide a module with a thin-film circuit comprising at least one capacitor whose capacitance value can be trimmed.

This object is achieved by means of a module provided with a thin-film circuit on a substrate of an insulating material which comprises at least one passive component having at least a first and a second electrically conducting layer and a dielectric, and in which at least one electrically conducting layer has a structured surface with recesses, a protective layer, and at least one contact hole which passes through the module, and a structured metallization which covers the module and the contact hole.

The recesses in the structured surface of the first or second electrically conducting layer, or in both electrically conducting layers, have the result that the passive component is composed of several capacitors connected in parallel. Accordingly, the capacitance value of the passive component is equal to the sum of the capacitance values of the parallel capacitors. The total capacitance value can be fine tuned through the removal of one or several of the small, parallel capacitors.

It is particularly preferred that the recesses have different widths.

It is furthermore preferred that the recesses have different mutual interspacings.

The accuracy with which the capacitance value can be trimmed depends on the design of the electrically conducting layer. The recesses give the electrically conducting layer a finger-type design. The more fingers of different widths there are in an electrically conducting layer, the more accurately the capacitance value can be adjusted.

It is furthermore preferred that the first electrically conducting layer and the second electrically conducting layer comprise Cu, Al, Al doped with Cu, Al doped with Mg, Al doped with Si, or Al doped with Si and Cu.

Electrically conducting layers made of these materials can be converted into a locally non-conducting state by means of focused laser emission and the accompanying heating effect thereof. Portions of the electrically conducting layer are evaporated by the occurring heating effect when these materials are used.

The invention further relates to a method of fine tuning the capacitance value of a passive component which comprises at least a first and a second electrically conducting layer as well as a dielectric, and in which at least one electrically conducting layer has a structured surface with recesses, in a module provided with a thin-film circuit on a substrate of an insulating material with a protective layer, with at least one contact hole which passes through the module, and with a structured metallization which covers the module and the contact hole, whereby a heating effect is achieved on at least one electrically conducting layer by means of focused laser emission, and portions of the electrically conducting layer are evaporated.

After the module provided with a thin-film circuit comprising at least one capacitor has been manufactured, the capacitance value of the capacitor is determined. The capacitance value is the sum of the capacitance values of the small, parallel capacitors which result from the recesses in the structured surface of at least one electrically conducting layer. Then a suitable number of parallel capacitors is eliminated by means of focused laser emission so as to obtain the desired capacitance value.

The invention will be explained in more detail below with reference to two Figures and an embodiment, where

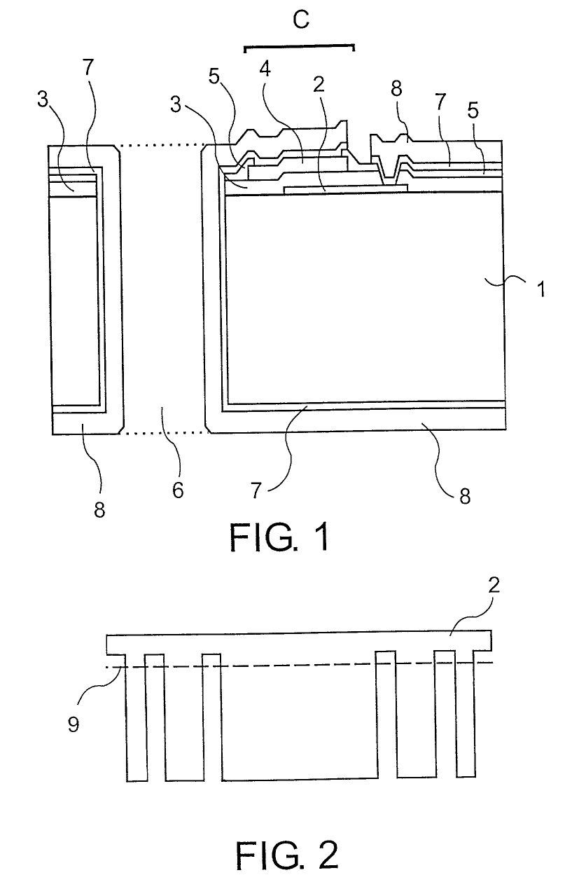

FIG. 1 diagrammatically shows the construction of a module provided with a thin-film circuit comprising a capacitor in cross-section, and

FIG. 2 shows an electrically conducting layer with recesses.

In FIG. 1, a module provided with a thin-film circuit has a substrate 1 which comprises, for example, a ceramic material, a glass-ceramic material, a glass material, or a ceramic material with a planarizing layer of glass or of an organic material. Preferably, the substrate 1 comprises Al₂O₃, glass, or Al₂O₃ with a planarizing layer of glass, polyimide, or polybenzocyclobutene. On this substrate 1, a first electrically conducting layer 2 is provided which has a structured surface with recesses. A dielectric 3 is present over this structured first electrically conducting layer 2, which dielectric 3 in general will cover the entire surface of the substrate 1 and is interrupted at certain areas only for realizing vias to the subjacent first electrically conducting layer 2. The dielectric 3 may comprise, for example, Si₃N₄, SiO₂, SiₓO_{y}N_{z} (0≦x≦1, 0≦y≦1, 0≦z≦1), or Ta₂O₅. A second electrically conducting layer 4 is deposited on the dielectric 3 and structured. The first electrically conducting layer 2 and the second electrically conducting layer 4 may comprise, for example, Cu, Al, Al doped with a few % of Cu, Al doped with a few % of Mg, Al doped with a few % of Si, or Al doped with a few % of Si and Cu. A protective layer of an inorganic material such as, for example, SiO₂, Si₃N₄, or SiₓO_{y}N_{z} (0≦x≦1, 0≦y≦1, 0≦z≦1) is provided over the entire region of the substrate 1. Alternatively, an organic material such as, for example, polyimide or polybenzocyclobutene may be used. In addition, the entire module has at least one contact hole 6. The module and the contact hole 6 are covered with a structured metallization which in its turn comprises at least one base layer 7. It may be preferred for a covering layer 8 to be provided on the base layer 7. In this case, the base layer 7, comprising, for example, Cr/Cu, serves as a nucleating layer for the electrochemical deposition of the covering layer 8. The covering layer 8 comprises, for example, Cu/Ni/Au.

Alternatively, the first and second electrically conducting layers 2 and 4, or only the second electrically conducting layer 4, may be structured after being deposited such that they have (or it has) recesses.

Furthermore, a barrier layer may be provided on the substrate 1, which layer comprises, for example, Si₃N₄. A resistance layer may also be deposited and structured on the substrate 1 or on the barrier layer. This structured resistance layer may comprise, for example, NiₓCr_{y}Al_{z} (0≦x≦1, 0≦y≦1, 0≦z≦1), SiₓCr_{y}O_{z} (0≦x≦1, 0≦y≦1, 0≦z≦1), SiₓCr_{y}N_{z} (0≦x≦1, 0≦y≦1, 0≦z≦1), CuₓNi_{y} (0≦x=1, 0≦y≦1), or TiₓW_{y} (0≦x=1, 0≦y≦1).

Furthermore, current supply contacts may be fastened to mutually opposed sides of the module. A current supply contact may be an electroplated SMD end contact of Cr/Cu, Ni/Sn, or Cr/Cu, Cu/Ni/Sn, or Cr/Ni, Pb/Sn, a bump end contact, a castellation of Cr/Cu, Cu/Ni/Au, a ball grid array comprising a Cr/Cu/Ni layer with a ball of Sn or a PbSn alloy, or a land grid array of Cr/Cu.

FIG. 2 shows an electrically conducting layer 2 with recesses. The widths of the recesses and the interspacings of the recesses may be chosen as desired. The electrically conducting layer 2 has a finger-type design owing to the recesses. The more fingers of different widths there are in the electrically conducting layer 2, the more accurately the capacitance value can be tuned. The cutting line 9 of the laser is also indicated. One or several fingers are cut off from the main portion of the electrically conducting layer 2 in this location by means of focused laser emission. The thin-film circuit has no metallization in this region.

An embodiment of the invention will be explained below, representing an example of how the invention may be realized.

Embodiment 1:

A first electrically conducting layer 2 of Al doped with 4% Cu was deposited on a substrate 1 of Al₂O₃ with a glass planarizing layer and structured by means of recesses such that a finger-type arrangement was obtained. The first electrically conducting layer 2 as a result had five fingers of different widths. In the next step, a dielectric layer 3 of Si₃N₄ was deposited over the entire surface of the substrate 1. A second electrically conducting layer 4 of Al doped with 4% Cu was deposited on the dielectric 3 and structured. The entire thin-film circuit was provided with a protective layer 5 of Si₃N₄. Vias were then etched through the protective layer 5 and the dielectric 3 so as to obtain an electrical contacting of the first electrically conducting layer 2. Several contact holes 6, passing fully through the module, were also created by means of a laser. A structured metallization comprising a base layer 7 of Cr/Cu and a covering layer 8 of Cu/Ni/Au was provided around the module and in the contact holes 6. In addition, ball grid arrays comprising a layer of Cr/Cu/Ni with Sn balls provided thereon were fastened on both sides of the module so as to serve as current supply contacts.

Then the total capacitance value of the capacitor composed of five smaller parallel capacitors was determined. Of these five capacitors or fingers, one finger contributed 70%, two fingers 10% each, and two fingers 5% each of the total capacitance value. Accordingly, the value of the total capacitance could be fine tuned by up to 30%. The maximum tolerance was ±2.5% here. The fine tuning of the capacitance value of the capacitor was achieved in that the relevant number of fingers was cut off from the electrically conducting layer 2. Portions of the electrically conducting layer 2 were evaporated along the laser cutting line 9 by focused emission of an argon laser in this process.

1. A module provided with a thin-film circuit on a substrate (1) of an insulating material which comprises at least one passive component having at least a first (2) and a second (4) electrically conducting layer and a dielectric (3), and in which at least one electrically conducting layer (2, 4) has a structured surface with recesses,
a protective layer (5), and
at least one contact hole (6) which passes through the module, and
a structured metallization which covers the module and the contact hole (6)

2. A module provided with a thin-film circuit as claimed in claim 1, characterized in that the recesses have different widths.

3. A module provided with a thin-film circuit as claimed in claim 1, characterized in that the recesses have different mutual interspacings.

4. A thin-film circuit provided with a component as claimed in claim 1, characterized in that the first electrically conducting layer (2) and the second electrically conducting layer (4) comprise Cu, Al, Al doped with Cu, Al doped with Mg, Al doped with Si, or Al doped with Si and Cu.

5. A method of fine tuning the capacitance value of a passive component which comprises at least a first (2) and a second (4) electrically conducting layer as well as a dielectric (3), and in which at least one electrically conducting layer (2, 4) has a structured surface with recesses,
in a module provided with a thin-film circuit on a substrate (1) of an insulating material with a protective layer (5),
with at least one contact hole (6) which passes through the module, and
with a structured metallization which covers the module and the contact hole (6),
by which method a heating effect is achieved on at least one electrically conducting layer (2, 4) by means of focused laser emission, and portions of the electrically conducting layer (2, 4) are evaporated.
